(19) United States
(12) Patent Application Publication
(10) Pub. No.: US 2016/0023242 A1
(43) Pub. Date: Jan. 28, 2016

(54) METHOD OF MAKING WAVELENGTH CONVERTERS FOR SOLID STATE LIGHTING APPLICATIONS

(71) Applicants: Darshan Kundaliya, Beverly, MA (US); Kailash C. Mishra, North Chelmsford, MA (US)

(72) Inventors: Darshan Kundaliya, Beverly, MA (US); Kailash C. Mishra, North Chelmsford, MA (US)

(73) Assignee: OSRAM SYLVANIA INC., Danvers, MA (US)

(21) Appl. No.: 14/444,504

(22) Filed: Jul. 28, 2014

(51) Int. Cl. B05D 3/06

(52) U.S. Cl. CPC B05D 3/065; H01L 2933/0041; H01L 33/50

(57) ABSTRACT

Disclosed herein are technologies utilizing sacrificial material layers for producing and transferring wavelength converters for light emitting devices via lift-off. In some embodiments the technologies utilize a precursor in the form of a substrate having a sacrificial layer formed thereon. The sacrificial layer may possess one or more properties that allow it to survive processing of a conversion layer formed thereon, and to facilitate removal of the substrate via a lift off process. In some embodiments the sacrificial layer may be configured to survive relatively high temperature processing without substantially affecting the performance of the conversion layer, and to facilitate removal of the substrate via laser lift off.

### FIELD

The present disclosure generally relates to wavelength converters and, more particularly, to technologies utilizing sacrificial material layers for the production of wavelength converters for light emitting devices.

### BACKGROUND

Solid state light sources such as light emitting diodes (LEDs) generate visible or non-visible light in a specific region of the electromagnetic spectrum depending on the material composition of the LED. When it is desired to construct an LED light source that produces a color different from the output color of the LED, it is known to convert the LED light output having a peak wavelength (“primary light”) to light having a different peak wavelength (“secondary light”) using photoluminescence.

Photoluminescence generally involves absorbing higher energy primary light by a wavelength converting material (“conversion material”) such as a phosphor or mixture of phosphors. This absorption excites the conversion material to a higher energy state. When the conversion material returns to a lower energy state, it emits secondary light, generally of a longer wavelength than the primary light. The peak wavelength of the secondary light can depend on the type of phosphor material. This process may be generally referred to as “wavelength conversion.” An LED combined with a wavelength converting structure that includes a conversion material such as phosphor to produce secondary light may be described as a “phosphor-converted LED” or “wavelength converted LED.”

In a known configuration, an LED die such as a III-nitride die is positioned in a reflector cup package and a volume. To convert primary light to secondary light, a wavelength converting structure (“wavelength converter”) may be provided. The wavelength converter may be integrated in the form of a self-supporting “plate,” such as a ceramic plate or a single crystal plate. In any case, the wavelength converter may be attached directly to the LED, e.g. by wafer bonding, sintering, gluing, etc. Such a configuration may be understood as “chip level conversion” or “CLC.” Alternatively, the wavelength converter may be positioned remotely from the LED. Such a configuration may be understood as “remote conversion.”

Numerous methods for forming wavelength converters and lighting devices including such converters are known in the art. For example a wavelength converter may be produced in the form of a self-supporting plate of phosphor material. Such a plate may be diced into a plurality of individual wavelength converters that are sized or otherwise configured for a particular lighting application. For example, the individual wavelength converters may be sized such that they are suitable for use in connection with one or more LEDs, in which case the converters may be arranged above the light emitting surface of an LED using known techniques such as pick and place technology. Alternatively or additionally, wavelength converters may be formed by depositing or growing one or more conversion materials on an LED wafer or die.

Although existing technologies for producing wavelength converters and light sources including such converters are useful, they may impose limitations on various characteristics of the converters that may be used. For example, pick and place technology may require the use of wavelength converters that are of a particular size and/or thickness. Similarly, processing parameters used to deposit a wavelength conversion material on an LED die may damage or adversely affect the performance of one or more components of the die. Interest therefore remains in the development of new techniques for producing wavelength converters and transferring them on to the corresponding light sources by new integration methodologies.

### BRIEF DESCRIPTION OF THE DRAWINGS

Reference is now made to the following detailed description which should be read in conjunction with the following figures:

FIG. 1 is a flow chart of example operations of one embodiment of a method for producing a wavelength converter consistent with the present disclosure.

FIGS. 2A-2G stepwise illustrate the formation of one example wavelength converter consistent with the present disclosure.

### DETAILED DESCRIPTION

The present disclosure will now proceed with reference to the accompanying drawings, in which example embodiments consistent with the present disclosure are shown. It should be understood that the examples in the figures are for the sake of illustration and ease of understanding only and that the methods, wavelength converters, and devices described herein may be embodied in many forms and are not limited to the illustrated embodiments in the figures or specific embodiments described herein.

References to the color of a phosphor, LED or conversion material refer generally to its emission color unless otherwise specified. Thus, a blue LED emits a blue light, a yellow phosphor emits a yellow light and so on.

As used herein, the terms “about” and “substantially,” when used in connection with a numerical value or range, mean +/−5% of the recited numerical value or range.

From time to time one or more aspects of the present disclosure may be described using ranges. In such instances it should be understood that the indicated ranges are exemplary only unless expressly indicated otherwise. Moreover, the indicated ranges should be understood to include all of the individual values of falling within the indicated range, as though such values were expressly recited. Moreover, the ranges should be understood to encompass subranges within the indicated range, as though such subranges were expressly recited. By way of example, a range of 1 to 10 should be understood to include 2, 3, 4 . . . etc., as well as the range of 2 to 10, 3 to 10, 2 to 8, etc., as though such values and ranges were expressly recited.

For the sake of the present disclosure, the term “primary light” refers to light emitted by a light source, such as a light emitting diode.

As used herein, the term “secondary light” means light produced by conversion of primary light by at least one first wavelength conversion material.

The term, “output light” is used herein to mean light that is output a light source, e.g., the combined light emission that is observed at a distance from a light source. Output light may include primary light, secondary light, tertiary light, combinations thereof, and the like. Without limitation, output light consistent with the present disclosure preferably has a color temperature ranging from about 2000K to about 6000K, such as about 4000K. Of course, output light having other color temperatures may be used and is envisioned by the present disclosure.

One or more elements of the present disclosure may be numerically designated, e.g., as a first, second, or third element. In this context it should be understood that the numerical designation is for the sake of clarity only (e.g., to distinguish one element from another), and that elements so designated are not limited by their specific numerical designation. Moreover the specification may from time to time refer to a first element as being “on” a second element. In that context it should be understood that the first element may be directly on the second element (i.e., without intervening elements there between), or that one or more intervening elements may be present between the first and second elements. In contrast, the term “directly on” means that the first element is present on the second element without any intervening elements there between.

As used herein singular expressions such as “a,” “an,” and “the” are not limited to their singular form, and are intended to cover the plural forms as well unless the context clearly indicates otherwise.

As used herein, the terms, “light emitting diode” and “LED” are used interchangeably, and refer to any light emitting diode or other type of carrier injection/junction-based system that is capable of generating radiation in response to an electrical signal. In particular, the term LED refers to light emitting diodes of all types (including semi-conductor and organic light emitting diodes) that may be configured to generate light in various portions of the electromagnetic spectrum. Non-limiting examples of suitable LEDs that may be used include various types of infrared LEDs, ultraviolet LEDs, red LEDs, green LEDs, blue LEDs, yellow LEDs, amber LEDs, orange LEDs, and white LEDs. Such LEDs may be configured to emit light over a broad spectrum (e.g., the entire visible light spectrum) or a narrow spectrum.

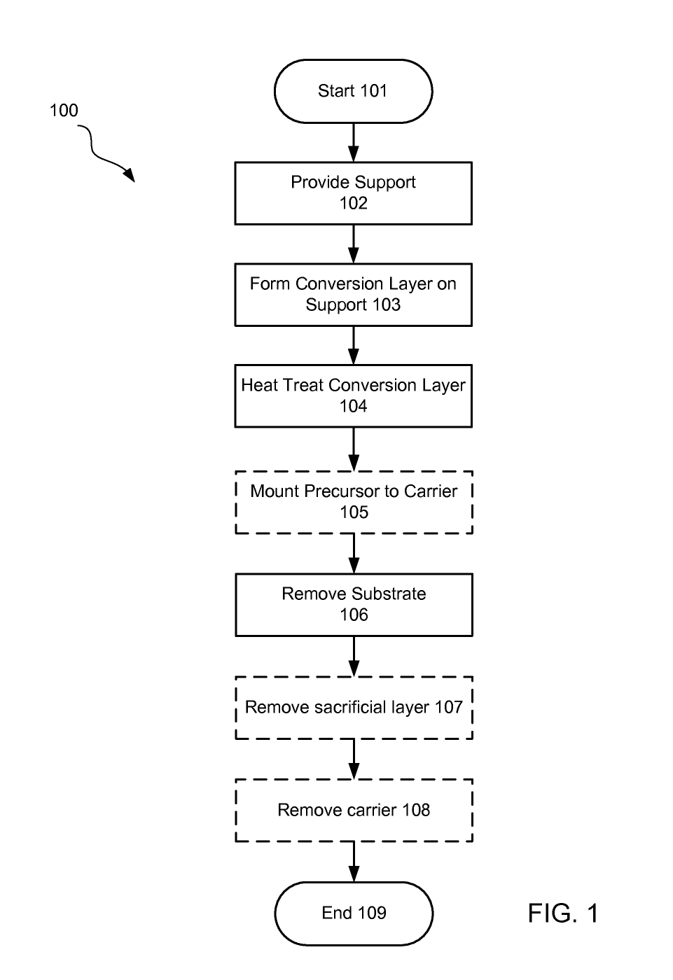

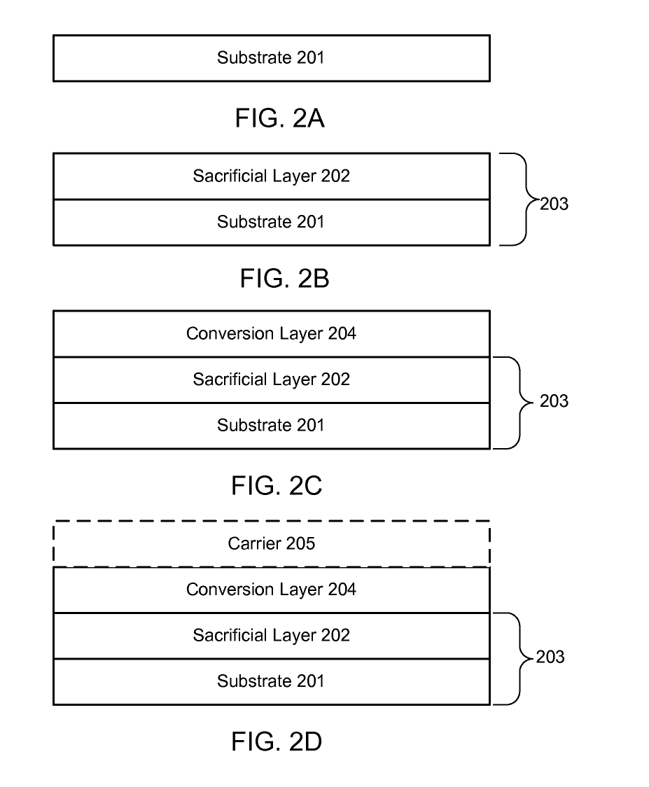

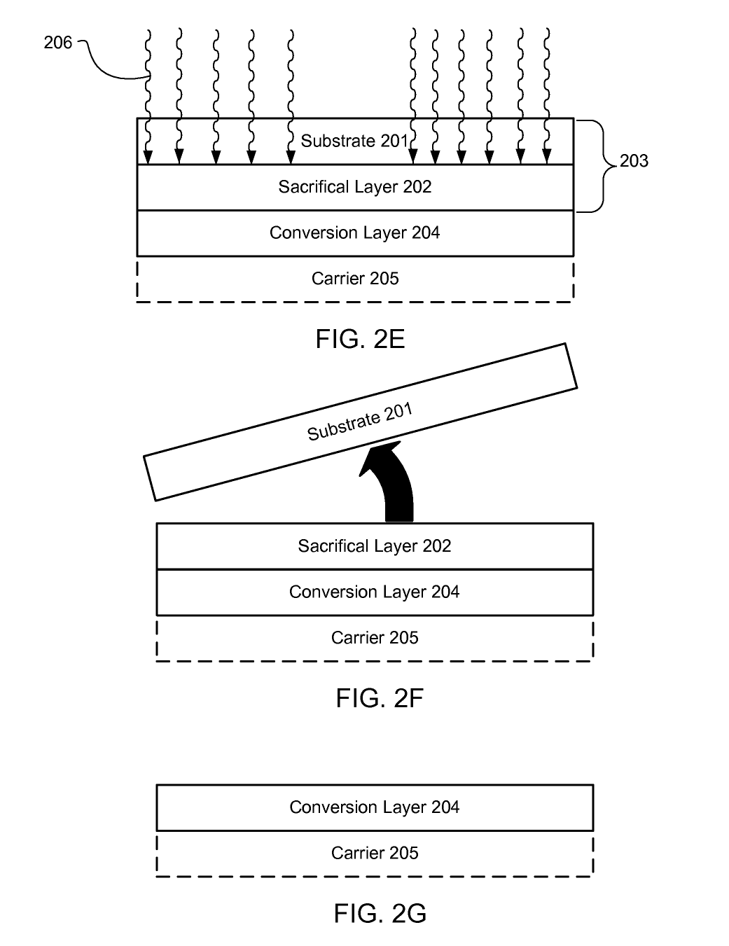

One aspect of the present disclosure relates to methods for producing a wavelength converter that is configured to convert primary light to secondary light. In this regard reference is made to FIG. 1, which is a flow chart of example operations of a method of forming a wavelength converter consistent with the present disclosure. As shown, method 100 begins at block 101. The method may then proceed to block 102, wherein a support may be provided. In general, the support may include a substrate upon which a sacrificial layer is formed. This concept is depicted in FIGS. 2A and B, which illustrate the formation of sacrificial layer 202 on substrate 201, so as to form support 203 (also referred to herein as a precursor, or precursor 203).

Substrate 201 may be formed of any suitable material. In some embodiments, substrate 201 is or includes one or more substrate materials which may support the formation of sacrificial layer 202 via one or more deposition or growth techniques. Non-limiting examples of such materials include sapphire, quartz glass, various types of garnets, other oxides, and combinations thereof. Without limitation, substrate 201 is preferably sapphire, such as r-plane or c-plane sapphire.

Sacrificial layer 202 may generally function to facilitate the separation of substrate 201 from other elements of a layer stack that may be used in the formation of a wavelength converter consistent with the present disclosure. For example and as will be described in detail below, sacrificial layer 202 may be configured to facilitate separation of substrate 201, e.g., via a lift off process that employs one or more light sources such as a laser. In such embodiments sacrificial layer 202 may facilitate removal of substrate 201 while remaining substantially intact. Therefore in some embodiments, substrate 201 may be removed without requiring the removal of sacrificial layer 202. Put in other terms, the methods described herein may remove substrate 201 from a layer stack without requiring the removal of at least a portion of sacrificial layer 202, and preferably without requiring the removal of substantially any of sacrificial layer 202.

As will also be described below, sacrificial layer 202 may also be configured such that it can withstand processing parameters that may be applied during other portions of the methods described herein, such as but not limited to a thermal treatment step that may be applied to adjust one or more properties of conversion layer 204. Without limitation, sacrificial layer 202 is preferably configured to withstand such processing conditions without substantially affecting one or more properties of conversion layer 204, such as the quantum efficiency of conversion layer 204.

“Without substantially affecting one or more properties of conversion layer 204” may be understood to mean that a relevant property of conversion layer 204 that is used in the methods described herein may be substantially the same as the properties of an otherwise identical conversion layer that was formed in the absence of a sacrificial layer consistent with the present disclosure. For example in some embodiments if a conversion layer formed in the absence of a sacrificial layer may exhibit a particular quantum efficiency value, e.g., 80%, the quantum efficiency of an identical conversion layer 204 that is used/formed in the manner described herein may exhibit a quantum efficiency within about 5% of 80%, despite the use of sacrificial layer 202.

With the foregoing in mind sacrificial layer 202 may be formed from or include one or more sacrificial materials. Examples of suitable sacrificial materials include but are not limited to various types of oxides (e.g., transition metal oxides and rare-earth oxides) and nitrides such as aluminum nitride (AlN), gallium nitride (GaN), silicon nitride (Si₃N₄, titanium nitride (TiN), zirconium nitride (ZrN), cerium oxide (CeO₂), beta gallium oxides (b-Ga₂O₃), hafnium oxide (HfO₂), zinc oxide (ZnO), zirconium oxide, boron nitride, combinations thereof, and the like. Without limitation, sacrificial layer 202 is preferably formed from an oxide such as CeO₂, HfO₂, and in some embodiments sacrificial layer 202 is CeO₂.

Sacrificial layer 202 may be formed on substrate 201 in any suitable manner, such as any suitable growth or deposition process. Non-limiting examples of suitable processes that may be used to form sacrificial layer 202 on substrate 201 include pulsed laser deposition (PLD), ion beam assisted PLD, sputtering, aerosol deposition, electron beam (e-beam) deposition, chemical vapor deposition, atomic layer deposition, combinations thereof, and the like. Without limitation, sacrificial layer 202 is preferably formed by depositing one or more sacrificial materials via PLD or e-beam deposition.

By way of example, in some embodiments one or more of the above noted sacrificial materials (e.g., CeO₂) may be deposited on substrate 201 (e.g., r-plane or c-plan sapphire) in a pulsed laser deposition chamber. Deposition may occur in an atmosphere of argon, nitrogen, hydrogen, combinations thereof, and the like. Without limitation, deposition of the above noted sacrificial materials is preferably performed in an oxygen atmosphere with a partial pressure ranging from about 1×10⁻⁸ torr to about 1 torr. The chamber temperature used in such a process may be any suitable temperature and may range for example from about 20° C. to about 1000° C. or more. Without limitation, the chamber temperature preferably ranges from about 700 to about 900° C., such as from about 800 to about 875° C. In some embodiments the sacrificial layer is formed by depositing CeO₂ in a PLD chamber at a chamber temperature of about 850° C.

The thickness of sacrificial layer 202 may vary widely. For example, the thickness of sacrificial layer may range from about 20 nanometers (nm) to about 5 microns, such as about 50 nm to about 4 microns, about 100 nm to about 3 microns, or even about 500 nm to about 3 microns. Without limitation, in some embodiments sacrificial layer 202 is formed from CeO₂ and has a thickness within the above noted ranges, such as between about 1 to about 3 microns.

While FIGS. 2A and 2B illustrate an example embodiment wherein precursor 203 includes a single sacrificial layer 202 that is formed directly on a first surface (not labeled) of substrate 201, such a structure is not required. Indeed in some embodiments, one or more additional layers may be present between substrate 201 and sacrificial layer 202. By way of example, sacrificial layer 202 may in the form of multiple layers of sacrificial material, either or both of which may have advantageous material properties such as those described herein. Alternatively or additionally, one or more other layers (e.g., an interface layer, buffer layer, etc., all not shown) may be formed on the first surface of substrate 201, after which sacrificial layer 202 may be formed on an exposed surface of the other layer(s).

Although the above description has focused on the formation of a precursor 203 including substrate 201 and sacrificial layer 202, it should be understood that the formation of such a precursor may not be required, particularly when precursor 203 is available through other means such as commercial channels. Therefore in some embodiments the formation of sacrificial layer 202 on substrate 201 may be omitted, and replaced with the mere provisioning of a precursor 203 that includes a substrate 201 having sacrificial layer 202 previously formed on a first surface thereof, either directly or on another layer.

In any case once sacrificial layer 202 is formed (or if precursor 203 is otherwise provided) the method may proceed to block 103, wherein a conversion layer may be formed on a surface of sacrificial layer 202. This concept is shown in FIG. 2C, which illustrates the formation of conversion layer 204 directly on the surface of sacrificial layer 202. Although conversion layer 204 is preferably formed directly on the surface of sacrificial layer 202, such a structure is not required. Indeed, one or more layers of other material may be formed between sacrificial layer 202 and conversion layer 204.

Conversion layer 204 may include one or more conversion materials that are configured to convert primary light (e.g., emitted from a light source such as an LED die) to secondary light. Non-limiting examples of suitable conversion materials that may be used in conversion layer 204 include phosphors such as oxide garnet phosphors and oxynitride phosphors. In some embodiments, the conversion material used in conversion layer 204 is or includes one or more phosphors selected from: garnets such as cerium activated yttrium aluminum garnet (Y₃Al₅O₁₂:Ce³⁺, also referred to herein as YAG:Ce), cerium activated lutetium aluminum garnet (Lu₃Al₅O₁₂:Ce³⁺), cerium activated terbium aluminum garnet (Tb₃Al₅O₁₂:Ce³⁺); nitride phosphors such as M₂Si₅N₈:Eu²⁺, wherein M=Ca, Sr, Ba; oxynitride phosphors such as MSi₂O₂N₂:Eu²⁺, wherein M=Ca, Sr, Ba; silicate phosphors such as BaMgSi₄O₁₀:Eu²⁺, M₂SiO₄:Eu²⁺, wherein M=Ca, Ba, Sr; combinations thereof, and the like. Alternatively or additionally, conversion layer 204 may include one or more conversion materials selected from MAlSiN₃:Eu, wherein M is a metal selected from Ca, Sr, Ba; A₂O₃:RE³⁺ wherein A is selected from Sc, Y, La, Gd, Lu and RE³⁺ is a trivalent rare earth ion such as Eu³⁺; other tertiary and higher metal oxide phosphors doped with divalent or trivalent rare earth ions such as Eu³⁺, Ce³⁺, Eu²⁺, Tb³⁺, etc., including functional groups like molybdates, niobates or tungstates. Of course, other conversion materials that may be known to those of skill in the art may also be used in conversion layer 204.

Without limitation, conversion layer 204 preferably includes or is formed by YAG:Ce and sacrificial layer 202 includes or is formed by CeO₂. As may be appreciated, YAG:Ce can convert light in the blue region of the visible spectrum to light in the yellow region.

Conversion layer 204 may be formed in any suitable manner, such as via pulsed laser deposition (PLD), ion beam assisted PLD, sputtering, electron beam deposition, aerosol deposition, and chemical vapor deposition. Without limitation, conversion layer 204 is preferably formed via PLD or ion beam assisted PLD.

In some embodiments conversion layer 204 may be formed by placing precursor 203 in a PLD chamber, after which conversion layer 204 may be deposited on a surface of sacrificial layer 202. Growth of the conversion layer 204 may proceed in an atmosphere of argon, nitrogen, hydrogen, or oxygen. Without limitation, formation of conversion layer 204 is preferably performed in an oxygen atmosphere with a partial pressure ranging from about 0.5 to about 10 milli-Ton (mTorr), such as about 1 to about 5 mTorr or even about 3 mTorr. The substrate temperature during deposition of conversion layer 204 may range from about 20° C. to 1000° C. Without limitation, the substrate temperature preferably ranges from about 500 to about 800° C., such as about 700° C. In some embodiments the conversion layer is formed by depositing YAG:Ce in a PLD chamber at a substrate temperature of about 40° C.

In some embodiments, conversion layer 204 is formed by depositing YAG:Ce in an atmosphere of argon and oxygen with an oxygen partial pressure of about 3 mTorr and substrate temperature of about 700° C. In this regard it is noted that PLD deposition of YAG:Ce is described in the following references: Jae Young Choe, “Luminuescence and compositional analysis of Y₃Al₅O₁₂:Ce films fabricated by pulsed-laser deposition” Mat. Res. Innovat., vol. 6, pp. 238-241 (2002); T. C. May-Smith “Comparative growth study of garnet crystal films fabricated by pulsed laser deposition,” Journal of Crystal Growth, Vol. 308, pp. 382-391 (2007); and M. Kottaisamy et al. “Color tuning of Y₃Al₅O₁₂:Ce phosphor and their blend for white LEDs,” Materials Research Bulletin, Vol. 34, pp. 1657-1663 (2008), the entire contents of which are incorporated herein by reference.

The thickness of conversion layer 204 may vary considerably. For example, the thickness of conversion layer 204 may range from about 0.5 microns to about 30 microns, such as about 1 to about 20 microns, or even about 1 to about 10 microns. Of course, conversion layer 204 may be formed to any other suitable thickness.

While FIG. 2C illustrates and the foregoing description explains a method in which conversion layer 204 is formed as a contiguous layer on a surface of sacrificial layer 202, it should be understood that such a structure is not required, and that conversion layer 204 may be formed in any suitable manner and with any suitable configuration. For example in some embodiments it may be desired to form isolated regions and/or a pattern of conversion layer 204 on sacrificial layer 202. This may be accomplished using any suitable technique, such as but not limited to photolithography. For example, prior to the deposition of conversion layer 204, a layer of photoresist (not shown) may be deposited on the upper surface of sacrificial layer 202, e.g., via spin coating or another suitable technique. Portions of the photoresist layer may then be exposed, e.g., to ultraviolet or other light as known in the art. Subsequent such exposure a developer may be applied to the photoresist layer to remove non-exposed regions of the photoresist layer.

Following application of the developer the remaining portion of the photoresist layer may form a pattern or other desired shape on the surface of sacrificial layer 202, in which a portion of the surface of sacrificial layer 202 is uncovered and a portion remains covered by exposed photoresist. The conversion material used to form conversion layer 204 may then be deposited as noted above, e.g. via PLD or e-beam deposition. Following such deposition the remaining photoresist with any conversion material formed thereon may be removed (e.g., by high temperature sintering) whereas conversion material deposited on the exposed surface of sacrificial layer 202 may remain. In this way, conversion layer 204 may be formed in a pattern or other desired distribution on the surface of sacrificial layer 202.

Returning to FIG. 1, after conversion layer 204 has been formed the method may proceed to block 104, wherein conversion layer 204 may be heat treated to adjust one or more of its properties, such as its quantum efficiency. For example in some embodiments conversion layer 204 as formed pursuant to block 103 may exhibit a first level of quantum efficiency. Without limitation, the first level of quantum efficiency may range from greater than 0 to less than about 70%, such as about 20 to about 60%. The heat treatment employed pursuant to block 104 may adjust the quantum efficiency of conversion layer to a second value of quantum efficiency that is greater than the first level of quantum efficiency. For example, the second level of quantum efficiency may range from about 60 to about 90% or more, such as about 70 to about 90, or even about 75 to about 85%. Without limitation, the second level of quantum efficiency exhibited by conversion layer 204 after heat treatment may range from about 70 to about 85%, such as about 75 to about 85% or even about 80 to about 85%. More generally, in some embodiments the second level of quantum efficiency exhibited by conversion layer 204 after heat treatment may be greater than about 60%, greater than about 70%, or even greater than about 80%. Without limitation, the second level of quantum efficiency exhibited by conversion layer 204 is preferably greater than about 70% or even more preferably greater than about 80%.

A wide variety of heat treatments may be applied pursuant to block 104 to adjust or more properties of conversion layer 204, such as its quantum efficiency. In some embodiments, the heat treatment performed pursuant to block 104 may be or may include annealing the structure of FIG. 2C at an elevated temperature, so as to adjust the quantum efficiency of conversion layer 204 from a first (as-deposited) value to a second (post heat treatment) value. In this regard, annealing of conversion layer 204 may be performed in any suitable manner, such as via microwave annealing, rapid thermal annealing, annealing in a furnace (e.g., a tube furnace, belt furnace, or the like), combinations thereof, and the like.

In some embodiments annealing of conversion layer 204 may be performed by exposing the structure of FIG. 2C to an annealing temperature (T1) for a specified period of time. T1 may range for example from greater than or equal to 1100° C. to about 3000° C., such as greater than or equal to about 1300, 1400, 1500, or 1600° C. to about 3000° C. The anneal time may range from several minutes to several hours or even one or more days. Without limitation, the anneal time preferably ranges from about 15 minutes to about 30 minutes. Without limitation, the structure of FIG. 2C may be preferably annealed in a belt furnace under a 6% hydrogen (balance nitrogen) gas environment at a temperature of about 1600° C. with a belt speed of 0.5 inch per minute. In other non-limiting embodiments, conversion layer 204 is YAG:Ce and heat treated by annealing in a furnace at a temperature T1 greater than or equal to about 1600° C. for about 30 minutes. After annealing, the YAG:Ce may exhibit a second level of quantum efficiency that is greater than or equal to about 60%, such as greater than or equal to about 70%, 80%, or even greater than or equal to about 90%.

As noted above, conversion layer 204 may be heat treated at relatively high temperature after it is deposited on sacrificial layer 202. It may therefore be desirable to select and/or configure sacrificial layer 202 such that it may withstand the heat treatment applied pursuant to block 104, and without substantially affecting one or more properties of conversion layer 204, such as its quantum efficiency.

Therefore in some embodiments sacrificial layer 202 may include or be formed from one or more sacrificial materials that have a melting point that exceeds the annealing temperature (T1) applied during the heat treatment of conversion layer 204. Without limitation, the sacrificial material(s) used in sacrificial layer 202 may exhibit a melting point ranging from greater than or equal to about 1400° C. or even greater than or equal to about 1600° C.

In some embodiments conversion layer 204 is YAG:Ce that is heat treated at greater than 1600° C. pursuant to block 104, and the sacrificial materials in sacrificial layer 202 have a melting point that is greater than or equal to about 1600° C. Non-limiting examples of sacrificial materials having a melting point greater than or equal to about 1600° C. include AlN, CeO₂, b-Ga₂O₃, HfO₂, TiN, ZnO, ZrN and ZrO₂. Without limitation, sacrificial layer 202 is preferably formed from CeO₂, which may exhibit a melting point of about 2400° C.

As may be appreciated when sacrificial material(s) in sacrificial layer 202 have a melting point that exceeds the annealing temperature, such materials may not melt when conversion layer 204 is heat treated pursuant to block 104. However, as will be described later, the melting point of the material(s) in sacrificial layer 202 may impact the amount of energy that is required to weaken or break the bond between sacrificial layer 202 and substrate 201, e.g., pursuant to a lift-off process. As such it may be desirable to select sacrificial materials for use in sacrificial layer 202 that have melting point that is higher than the annealing temperature applied pursuant to block 104, but which is not excessively high. Therefore in some embodiments the melting point of the sacrificial material(s) used in sacrificial layer 202 may range from greater than 1600° C. to about 2500° C., such as greater than 1600° C. to about 2400° C. Non-limiting examples of such materials include CeO₂, b-Ga₂O₃, HfO₂ and ZnO. Again without limitation, sacrificial layer 202 is preferably formed from CeO₂.

As conversion layer 204 is heat treated at relatively high temperature, thermal degradation (e.g., pyrolysis, ion generation, etc.) may occur. In such instances, there is a potential for ions, degradation products or other components of sacrificial layer 202 to migrate into and potentially affect one or more properties of conversion layer 204. For example, as conversion layer 204 is heat treated, ions or other components of sacrificial layer 202 may migrate into conversion layer 204 and negatively impact its quantum efficiency. It may therefore be desirable to form sacrificial layer 202 from sacrificial materials that do not thermally degrade and/or which do not substantially thermally degrade during the heat treatment process.

Therefore in some embodiments sacrificial layer 202 may include or be formed from sacrificial materials that have a thermal degradation point (under the gas environment used during heat treatment) that exceeds the temperature (e.g., the annealing temperature T1) applied pursuant to block 104 of FIG. 1. Without limitation, the sacrificial material(s) used in sacrificial layer 202 may exhibit a thermal degradation point ranging from greater than or equal to about 1400° C., or even greater than or equal to about 1600° C. In some embodiments, the thermal degradation point of the sacrificial materials used in sacrificial layer 202 is greater than 1600° C. CeO₂ is one example of a sacrificial material exhibiting a thermal degradation point greater than 1600° C., although other materials meeting this relationship may also be used (e.g. AlN, ZrO₂ and the like).

Put in other terms, sacrificial layer 202 may be configured such that ions, degradation products, or other components thereof do not or do not substantially migrate to within conversion layer 204 during the heat treatment processes noted above. This may be understood to mean that during heat treatment, ions or other components may migrate into conversion layer 204 to a distance D that is less than 10% of the thickness of conversion layer 204, such as less than 5% or even less than 1% of the thickness of conversion layer 204.

Alternatively or additionally, sacrificial layer 202 may be configured such that it does not substantially affect one or more properties of conversion layer 204, despite being exposed to relatively high temperatures during the thermal treatment applied pursuant to block 104. This may be understood to mean that one or more properties of conversion layer 204 may exhibit a first value when heat treated as discussed above in the presence of sacrificial layer 202, wherein the first value is within about 5% of the value of the same property exhibited by an identical conversion layer that is identically heat treated in the absence of a sacrificial layer. For example, a conversion layer 204 heat treated in accordance with the present disclosure in the presence of sacrificial layer 202 may exhibit a quantum efficiency of about 80%, which may be within 5% of the quantum efficiency of an identical conversion layer that is identically heat treated in the absence of sacrificial layer 204. One example of a conversion material that may satisfy this relationship is CeO₂, although other materials meeting this relationship may also be used.

Returning to FIG. 1, following heat treatment of conversion layer 204 the method may proceed to optional block 105, wherein the structure of FIG. 2C may be optionally mounted to a carrier. This concept is illustrated in FIG. 2D, which illustrates optional carrier 205 mounted to a surface of conversion layer 204.

Carrier 205 may be formed of any suitable material. Non-limiting examples of suitable materials that may be used to form carrier 205 include light emitting devices such as one or more wafer level light emitting diodes and/or organic light emitting diodes, and non-light emitting carriers such as glass, copper, polycarbonate, polyimide, other organic or inorganic materials, combinations thereof, and the like. Without limitation carrier 205 is preferably a light emitting device such as one or more light emitting diodes.

Carrier 205 may be mounted to conversion layer 204 in any suitable manner. In some embodiments carrier 205 may be direct bonded to conversion layer 204, e.g., without the use of an adhesive. Alternatively, one or more adhesives may be used to couple carrier 205 to conversion layer 204. Non-limiting examples of suitable adhesives include silicones, epoxies, crystabolite wax, low melting point glass, other organic or inorganic adhesives, tape, metals, combinations thereof, and the like. When used, an adhesive may be in the form of an adhesive layer (not shown) that is present between conversion layer 204 and carrier 205. Alternatively or additionally, carrier 205 may be mechanically coupled to the structure of FIG. 2C such that a surface of carrier 205 is proximate a surface of conversion layer 204.

In some embodiments carrier 205 is or includes one or more light emitting diodes. By way of example, carrier 205 may include a plurality of light emitting diodes which are formed on or adhered to the surface of a substrate. In such instances the structure of FIG. 2D may be coupled to carrier 205 using any suitable mechanism. By way of example, the structure of FIG. 2D and carrier 205 may be oriented such the light emitting surface of one or more LEDs on carrier 205 faces the upper surface (as depicted in FIG. 2D) of conversion layer 204. In instances where conversion layer 204 has been patterned or formed in isolated regions, orientation of carrier 205 and the structure of FIG. 2D may further include aligning the portions of conversion layer 204 with the light emitting surface of corresponding LEDs on carrier 205. Carrier 205 and the structure of FIG. 2D may then be engaged, e.g., by bringing carrier 205 and the upper surface of conversion layer 204 together. Coupling of the structure of FIG. 2D and carrier 205 may then be accomplished in any suitable manner as noted above. Without limitation, mounting of carrier 205 to the structure of FIG. 2D is preferably accomplished via bonding, e.g., with an adhesive that was previously applied to the appropriate surface of carrier 205, conversion layer 204, or a combination thereof.

Returning to FIG. 1, once the precursor is mounted to a carrier (or if such mounting is omitted) the method may proceed to block 106, wherein the substrate may be removed. This concept is illustrated in FIGS. 2E and F, which illustrate the separation of substrate 201 from sacrificial layer 202.

Substrate 201 may be removed by any suitable process. Without limitation, substrate 201 is preferably removed using a lift off process, such as a laser lift off process. Therefore in some embodiments, removal of substrate 201 is facilitated at least in part by irradiating precursor 203 (with conversion layer 204 and optional carrier 205 thereon) with light having a wavelength λ1. In this regard, substrate 201 may be configured to transmit light of wavelength λ1, whereas sacrificial layer 202 may be configured to efficiently absorb light of wavelength λ1. As will be understood by those of skill in the art, the absorption of λ1 by sacrificial layer 202 will result in the production of heat that can weaken or even break the physical and/or chemical bonds of sacrificial layer to weaken the bond between substrate 201 and sacrificial layer 202. As a result, substrate 201 may automatically release from substrate 201 and/or may be removed by the application of mechanical force while leaving sacrificial layer 202 substantially intact.

The foregoing concept is shown in FIGS. 2E and F, wherein light 206 having wavelength λ1 is depicted as being transmitted through substrate 201 to impinge on sacrificial layer 202. Light 206 may be produced by any suitable light source, such as laser and non-laser sources. Without limitation, light 206 is preferably produced by a laser, including nitrogen lasers and excimer lasers based on Ar₂*, ArBr*, ArCl*, F₂*, ArF*, KrF*, NeF*, Kr₂*, KrBr*, KrCl*, KrI*Xe₂*, XeBr*, XeCl*, XeI* excimers, combinations thereof, and the like. Wavelength λ1 may be any suitable wavelength within the ultraviolet, visible, or infrared regions of the spectrum. Without limitation, λ1 is preferably in the ultraviolet region of the spectrum. In some embodiments, λ1 is 400 nm or less, such as about 50 to about 400 nm or even about 150 to 400 nm. In specific non-limiting embodiments, λ1 is 355 nm, 248 nm, or 193 nm.

Light 206 may be applied at any suitable flux, wherein flux may be represented in joules per square centimeters (J/cm²). In some embodiments, light 206 may have a flux ranging from about 0.1 to about 5 J/cm², such as about 0.1 to 3.5 J/cm². As may be appreciated, such fluxes may be considerably lower than the fluxes applied in laser lift off processes used in conjunction with the production of gallium nitride LEDs.

To enable transmission of λ1 through substrate 201, substrate 201 may be configured to have a first band gap energy (BG₁) that exceeds the energy (E_{L}) of light 206 of wavelength λ1. As will be understood by those skilled in the art, the energy of a photon of light can be calculated using the equation E=hc/X, wherein E is the energy in joules, h is Plancks constant, c is the speed of light, and λ is the wavelength of the light in question. E can be converted to electron volts using the conversion 1 joule (J)=6.24×10¹⁸ electron volts (eV). It should therefore be understood that when λ1 is 355, 248 or 193 nm, the energy of that light is 3.49 eV, 4.99 eV, and 6.42 eV, respectively. Put in other terms, λ1 may have an energy E_{L} ranging from about 3 to about 6.5 eV and BG₁ may be greater than E_{L}. Sapphire is one non-limiting example of a substrate material that may exhibit a band gap energy BG₁ consistent with the foregoing ranges.

As noted above, sacrificial layer 202 is preferably configured to efficiently absorb λ1, so as to create heat proximate the interface between sacrificial layer 202 and substrate 201. To enable efficient absorption of λ1, sacrificial layer 202 preferably has a band gap energy BG₂ that is less than the energy of light of wavelength λ1. Put in other terms, λ1 may have an energy E_{L} ranging from about 3 to about 6.5 eV, and BG₂ may be less than E_{L}. In some embodiments, BG₂ ranges from about 3 to about 6 eV, such as about 3.6 to about 4.1 eV. One example of a sacrificial material that has a band gap within such ranges is CeO₂, although other suitable materials may also be used.

To summarize the foregoing, in some embodiments light 206 may have an energy E_{L}, substrate 201 may have a first band gap energy BG₁, and sacrificial layer 202 may have a second band gap energy BG₂, wherein the following relationship is met: BG₂<E_{L}<BG₁.

As noted above, absorption of light 206 by sacrificial layer 202 may result in the generation of heat proximate the interface between substrate 201 and sacrificial layer 202. This heat may weaken or break bonds of the sacrificial layer and hence weaken the bond between substrate 201 and sacrificial layer 202, thereby facilitating the removal of substrate 201. With this in mind, it may be desirable to configure sacrificial layer 202 such that heat generated by the absorption of light 206 is concentrated at a region proximate the interface between sacrificial layer 202 and substrate 201. One way this may be accomplished is by forming sacrificial layer 202 out of materials that have relatively low thermal conductivity. By limiting the thermal conductivity of sacrificial layer 202, the transfer of heat generated by the absorption of light 206 may be correspondingly limited. As a result, such heat may be isolated at the interface between sacrificial layer 202 and substrate 201.

By way of example, sacrificial layer 202 may include or be formed of materials that exhibit a thermal conductivity ranging from greater than 0 to about 50 watts per meter kelvin (W/(m·K)), such as about 0.4 to about 25 W/(m·K), or even about 0.5 to about 5 W/(m·K). Without limitation, sacrificial layer 202 preferably exhibits a thermal conductivity that is less than 1 W/(m·K), such as about 0.5 W/(m·K). Examples of materials that may exhibit thermal conductivity in these ranges include CeO₂ (0.5 W/(m·K)), HfO₂ (23 W/(m·K)), Si₃N₄ (30 W/(m·K)), TiN (25 W/(m·K)), ZnO (2-5 W/(m·K)), and ZrO₂ (2.2 W/(m·K)). Without limitation, sacrificial layer is preferably formed from CeO₂.

Consistent with the foregoing, laser lift off may proceed by irradiating precursor 203 (including conversion layer 204 and carrier 205). As shown in FIGS. 2E and F, light 206 may be transmitted through substrate 201 to impinge on sacrificial layer 202. As noted above sacrificial layer 202 may absorb and convert light 206 into heat, which may be concentrated at an interface between substrate 201 and sacrificial layer 202. Such heat may weaken or even break the chemical and/or physical bonds of the sacrificial layer and hence weaken the bond between substrate 201 and sacrificial layer 202. As a result, substrate 201 may autonomously “lift off” or disengage from sacrificial layer 202. Alternatively or additionally, removal of substrate 201 may be further facilitated by the application of mechanical force, if needed. In any case, removal of substrate 201 may leave sacrificial layer 202 substantially intact as shown in FIG. 2F.

Once substrate 201 is removed the method of FIG. 1 may proceed to optional block 107, wherein sacrificial layer 202 may optionally be removed. When desired, removal of sacrificial layer 202 may be accomplished in any suitable manner. In some embodiments, sacrificial layer 202 may be removed by chemical etching, exposure to ultraviolet radiation, reactive ion etching, combinations thereof, and the like. Without limitation, sacrificial layer 202 is preferably removed by chemical etching. In any case, removal of sacrificial layer 202 may result in the structure shown in FIG. 2G, in which conversion layer 204 may be isolated or disposed on optional carrier 205.

Once sacrificial layer 202 is removed or if such removal is not desired, the method may proceed to optional block 108, wherein optional carrier 205 may be removed. Of course, this step may be omitted in instances where carrier 205 is not used or if removal of carrier 205 is not desired. When carrier 205 has been used and its removal is desired, removal of carrier 205 may be accomplished in any suitable manner. For example where carrier 205 has been adhered to conversion layer 204 with an adhesive, removal of carrier 205 may be accomplished by mechanical removal of carrier 205, either along in conjunction with a process to weaken or dissolve the adhesive.

The method may then proceed to block 109 and end, at which time a wavelength converter consistent with the present disclosure may be produced.

### EXAMPLE

For the sake of illustration the present disclosure will now proceed to describe several examples of wavelength converters consistent with the present disclosure. It should be understood that the following examples are representative only, and should not be considered to represent then entire scope of the invention described herein.

In this example wavelength converters were manufactured by growing sacrificial layers of CeO₂ on sapphire substrates, so as to produce precursors. Specifically, a CeO₂ sacrificial layer was grown on each sapphire substrate via pulsed laser deposition at a temperature of about 850° C. in an atmosphere with an argon or oxygen partial pressure of about 1×10⁻⁶ to about 400 mTorr. A layer of YAG:Ce was then grown on the CeO₂ sacrificial layer of each stack using pulsed laser deposition at 850° C. in an atmosphere with an oxygen partial pressure of 3 mTorr.

The resulting stacks were then heat treated at 1600° C. The quantum efficiency of the YAG:Ce layers in each stack was measured, with some of the layers exhibiting a quantum efficiency of about 80%. The stack of each sample was also examined using scanning electron microscopy, which showed that the sapphire substrate and CeO₂ sacrificial layer of each stack remained substantially intact after the heat treatment.

Subsequently the stack of each sample was mounted to a blue light emitting diode device or blue light emitting diode wafer using an adhesive such as a silicone glue, crystabolite wax, etc. such that each carrier was proximate the YAG:Ce layer. The resulting structures were then irradiated with a laser having a wavelength of 193 nm or 248 nm. The laser light first impinged on the exposed surface of the sapphire substrate. All or nearly all of the laser light transmitted through the sapphire substrate was absorbed by the corresponding CeO₂ sacrificial layer. In some instances this resulted in the release of the sapphire substrate without the application of mechanical force. In other instances mechanical force was applied to remove the substrate. In any case, the CeO₂ sacrificial layer of each sample was were inspected via scanning electron microscopy and was determined to be substantially intact following removal of the sapphire substrate.

The resulting structures were then further processed to remove the CeO₂ sacrificial layers via wet chemical etching or reactive ion etching (RIE) resulting in YAG:Ce wavelength converters of the structure shown in FIG. 2G.

Other than in the examples, or where otherwise indicated, all numbers expressing endpoints of ranges, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the present disclosure are approximations, unless otherwise indicated the numerical values set forth in the specific examples are reported as precisely as possible. Any numerical value, however, inherently contains certain errors necessarily resulting from the standard deviation found in their respective testing measurements.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of forming a wavelength converter, comprising:
forming a conversion layer on a support, the support comprising a substrate having a sacrificial layer formed thereon, the conversion layer capable of converting a primary light into a secondary light;
heat treating at least the conversion layer at a first temperature (T1) to adjust at least one property of the conversion layer;
irradiating the sacrificial layer through the substrate with light having a wavelength (λ1) emitted from a light source, so as to facilitate separation of said substrate from said sacrificial layer; and
separating said substrate from said sacrificial layer;
wherein:
said sacrificial layer comprises a sacrificial material having a melting temperature greater than T1 and a thermal decomposition temperature greater than T1.

2. The method of claim 1, wherein said heat treating is performed at a temperature greater than or equal to about 1600° C.

3. The method of claim 2, wherein said sacrificial material and constituents thereof do not substantially migrate into said conversion layer during said heat treating.

4. The method of claim 1, wherein said light source is a laser, λ1 has an energy (E_{L}) said substrate has a first band gap energy (BG₁), said sacrificial layer has a second band gap energy (BG₂), and BG₂<E_{L}<BG₁.

5. The method of claim 4, wherein BG₂ ranges from about 3 to about 6 electron volts (eV).

6. The method of claim 2, wherein said sacrificial material is an oxide or a nitride.

7. The method of claim 4, wherein said sacrificial material is selected from the group consisting of AlN, CeO₂, b-Ga₂O₃, GaN, HfO₂, Si₃N₄, TiN, ZnO, ZrN, and ZrO₂.

8. The method of claim 1, wherein said sacrificial material is CeO₂.

9. The method of claim 1, wherein said sacrificial layer consists essentially of CeO₂.

10. The method of claim 1, wherein said conversion layer includes at least one phosphor selected from the group consisting of: cerium-activated yttrium aluminum garnet, cerium-activated yttrium gadolinium aluminum garnet, cerium-activated lutetium aluminum garnet, europium- or cerium-activated alkaline earth silicon oxynitride, and europium- or cerium-activated silicon aluminum oxynitride phosphor.

11. The method of claim 1, wherein said conversion layer comprises cerium activated yttrium aluminum garnet.

12. The method of claim 1, wherein said substrate is sapphire.

13. The method of claim 1, wherein said sacrificial material has a thermal conductivity of less than or equal to about 5 watts per meter kelvin (W/(m·K)).

14. The method of claim 1, wherein said at least one property comprises a quantum efficiency of said conversion layer.

15. The method of claim 14, wherein after said heat treating, the quantum efficiency of said conversion layer is greater than about 70%.

16. The method of claim 1, further comprising mounting a carrier to the conversion layer prior to said irradiating.

17. The method of claim 16, wherein said carrier comprises at least one light emitting diode having a light emitting surface, and said mounting comprises coupling said light emitting surface to said conversion layer.

18. The method of claim 1, wherein during said irradiating:
at least a portion of said light having a wavelength λ1 is transmitted through said substrate to impinge on said sacrificial layer; and
said sacrificial layer absorbs at least a portion of said light so as to generate heat substantially at an interface between said sacrificial layer and said substrate, wherein said heat is sufficient to weaken physical bonds between said substrate and said sacrificial layer.

19. The method of claim 1, wherein the sacrificial layer comprises CeO₂ and the substrate is sapphire.

20. The method of claim 13, wherein said light source is a laser, λ1 has an energy, E_{L}, said substrate has a first band gap, BG₁, said sacrificial layer has a second band gap, BG₂, and BG₂<B_{L}<BG₁.
